(19) United States
(12) Patent Application Publication
(10) Pub. No.: US 2006/0223299 A1
(43) Pub. Date: Oct. 5, 2006

(54) Fabricating process of an electrically conductive structure on a circuit board

(76) Inventor: Wen-Heng Hu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/295,003

(22) Filed: Dec. 5, 2005

(30) Foreign Application Priority Data
Mar. 29, 2005 (TW) 094109711

(51) Int. Cl. H01L 21/44

(52) U.S. Cl. 438/613; 438/678

(57) ABSTRACT

The fabricating process of an electrically conductive structure on a circuit board includes: providing a circuit board with a plurality of electrically connecting pads formed thereon; forming a first insulating layer on the circuit board, the first insulating layer covering the electrically connecting pads; forming a conductive layer on the first insulating layer; forming a second insulating layer on the conductive layer; applying an opening process to the first insulating layer, the conductive layer and the second insulating layer directly over the electrically connecting pads to form openings through the three layers corresponding in position to the electrically connecting pads; and forming bumps in the opening by electroplating. The fabricating process of the present invention can reduce the number of alignment steps and fabricating cost.

### FIELD OF THE INVENTION

The present invention relates to a fabricating process of a conductive structure of a circuit board, and more particularly to fabricating a conductive structure on surface of a circuit board.

### BACKGROUND OF THE INVENTION

Due to gradually reduced size and integrated multiple functions of electronic products, semiconductor packages are accordingly required high integration and miniaturization such as flip-chip packages that have become the mainstream technology in the market.

The main structure of the flip-chip packages includes a plurality of metal connecting elements respectively formed on electrically connecting pads of a circuit board. FIGS. 3A to 3I show a conventional fabricating process of the metal connecting elements.

Referring to FIG. 3A, a plurality of electrically connecting pads 211 are formed on a circuit board 21 to function as output/input connecting points.

Referring to FIG. 3B, a first insulating layer 22 made of photoimagable material is formed on the circuit board 21.

Referring to FIG. 3C, the first insulating layer 22 is patterned by exposure and development to form a plurality of first openings 221 directly over the electrically connecting pads 211 to expose the electrically connecting pads 211 via the first openings 221.

Referring to FIG. 3D, a conductive layer 23 such as a seed layer is formed on the surface of the first insulating layer 22, the conductive layer 23 being electrically connected the electrically connecting pads 211.

Referring to FIG. 3E, a second insulating layer 24 is made of photoimagable material formed on the conductive layer 23, which is further exposed and developed to form second openings 241 corresponding to the electrically connecting pads 211 to expose the conductive layer 23.

Referring to FIG. 3F, bumps 25 made of solder material with low melting point are formed in the second openings 241 by electroplating through the conductive layer 23 as a current conductive path.

Referring to FIGS. 3G and 3H, the second insulating layer 24 and the conductive layer 23 underneath the second insulating layer 24 are removed to expose the bumps 25.

Referring to FIG. 3I, the bumps 25 are reflowed to form semi-spherical metal connecting elements 25′ that can be connected with outside circuits.

In the above conventional fabricating process, the first insulating layer 22 and the second insulating layer 24 both need two fabricating processes: exposure and development. Moreover, the patterning onto the second insulating layer 24 should be aligned before exposure such that the second openings can be aligned with the first openings exactly. Because the diameter of the first openings 221 and the second openings 241 are fine, it is not easy to implement the alignment. Thus, the diameter of the second openings 241 is usually designed to be two times bigger than that of the first openings 221 to make the alignment easier. However, the second openings 241 that are enlarged occupy more space, accordingly, it becomes impossible to meet the requirement of the fine pitch and increase the number of the solder pads.

Moreover, the complicated fabricating process in the prior art results in high fabricating cost and slow fabricating speed.

Therefore, the problem to be solved here is to provide an improved fabricating process, which can avoid the above prior-art drawbacks so as to simplify the fabricating process and reduce the fabricating cost.

### SUMMARY OF THE INVENTION

According to the above defects, a primary objective of the present invention is to provide a simplified fabricating process of a conductive structure on a circuit board.

Another objective of the present invention is to provide a fabricating process of a conductive structure on a circuit board which can speed up the fabricating process.

A further objective of the present invention is to provide a fabricating process of a conductive structure on a circuit board which can meet the requirement of the fine pitch.

Still another objective of the present invention is to provide a fabricating process of a conductive structure on a circuit board which can reduce the fabricating cost.

To achieve the above and other objectives, the fabricating process of the present invention includes: providing a circuit board with a plurality of electrically connecting pads formed thereon; forming a first insulating layer on the circuit board which covers the electrically connecting pads; forming a conductive layer on the first insulating layer; forming a second insulating layer on the conductive layer; applying an opening process to the first insulating layer, the conductive layer and the second insulating layer directly over the electrically connecting pads to form openings in the three layers corresponding in position to the electrically connecting pads; and forming bumps in the opening by electroplating.

The present invention directly forms openings through the first insulating layer, the conductive layer and the second insulating layer to expose the electrically connecting pads and the conductive layers such that the bumps can be formed through the conductive layer and electrically connected with the electrically connecting pads. Thus, the present invention avoids the two-time opening processes of the prior art and simplifies the fabricating process, thereby speeding up fabricating process and reducing fabricating cost.

In addition, because the present invention needs not increase the diameter of the openings to reduce the alignment difficulty, the diameter of the openings of the present invention can be designed much smaller, which makes it easy to meet the requirement of the fine pitch, thereby increasing the number of the electrically connecting pads per unit area.

### BRIEF DESCRIPTION OF DRAWINGS

FIGS. 1A to 1I are cross-sectional diagrams illustrating a fabricating process of a conductive structure on a circuit board according to a first embodiment of the present invention;

FIGS. 2A to 2K are cross-sectional diagrams illustrating a fabricating process of a conductive structure on a circuit board according a second embodiment of the present invention; and

FIGS. 3A to 3I are cross-sectional diagrams illustrating a fabricating process of a conductive structure of the prior art.

### DETAILED DESCRIPTION OF PREFERRED EMBODIMENTS

Hereunder, embodiments of the present invention will be described in full detail with reference to the accompanying drawings.

### First Embodiment

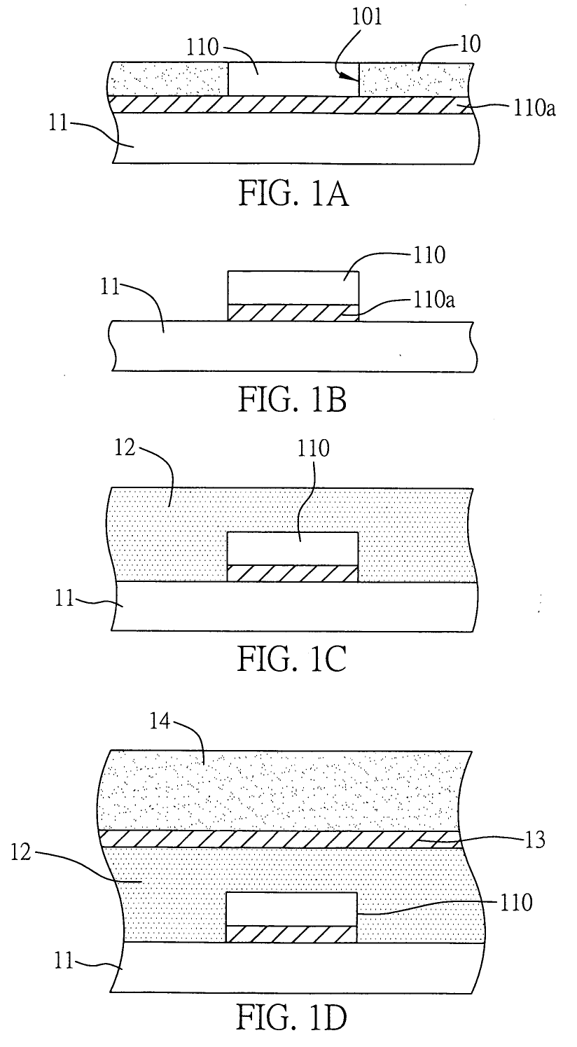

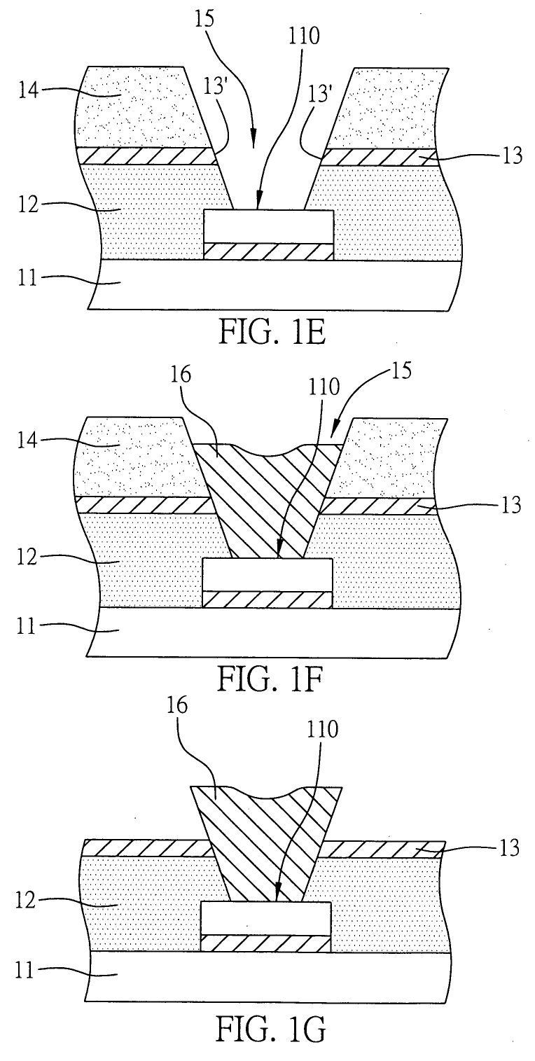

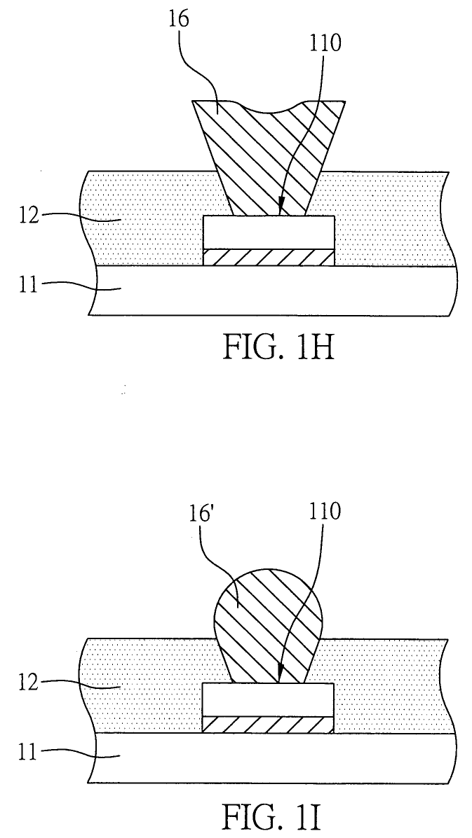

FIGS. 1A to 1I show a fabricating process of a solder pad according to a first embodiment of the present invention.

As shown in FIG. 1A, a circuit board 11 with a conductive layer 110a formed thereon is provided first. The conductive layer 110a can be formed of a metal or an alloy selected from Cu, Sn, Ni, Cr, Ti, Cu—Cr alloy or Sn—Pb alloy or formed of a conductive polymer material. Then, a resist layer 10 such as a dry-film photoresist layer or a liquid photoresist layer patterned with openings 101 is formed on the surface of the conductive layer 110a. Subsequently, a plurality of electrically connecting pads 110 are formed in the openings 101 of the resist layer 10 by electroplating.

As shown in FIG. 1B, the resist layer 10 and the conductive layer 110a underneath the resist layer 10 are removed to expose the electrically connecting pads 110.

As shown in FIG. 1C, a first insulating layer 12 covering the electrically connecting pads 110 is formed on the circuit board 11 by lamination, coating or printing. The first insulating layer 12 can be an organic solder resist layer such as solder mask.

As shown in FIG. 1D, a conductive layer 13 is formed on the first insulating layer 12 by electroplating, electroless plating or sputtering. The conductive layer 13 can be formed of a metal or an alloy or several laminated metal layers selected from Cu, Sn, Ni, Cr, Ti, Cu—Cr alloy or Sn—Pb alloy or formed of a conductive polymer material. Then, a second insulating layer 14 is formed on the surface of the conductive layer 13 by lamination, coating or printing. The second insulating layer 14 can be made of photoimagable material such as dry film or non-photoimagable material such as PET plastic or blue tape.

As shown in FIG. 1E, a laser opening process is applied to the first insulating layer 12, the conductive layer 13 and the second insulating layer 14 directly above the electrically connecting pads 110 to form openings 15 to expose the electrically connecting pads 110 and the edges 13′ of the conductive layer 13 via the openings 15.

As shown in FIG. 1F, bumps 16 are formed in the openings 15 by electroplating through the conductive layer 13 as a current conductive path. The bumps 16 can be made from a metal or an alloy selected from Pb, Sn, Ag, Cu, Bi, Sb, Zn, Ni, Zr, Mg, In, Te, Au and Ga. The bumps 16 contact with the electrically connecting pads 110 after the bumps 16 formed in the openings 15 reach a certain thickness.

As shown in FIG. 1G, the second insulating layer 14 is removed by chemical stripping or physics stripping to expose upper portion of the bumps 16. The second insulating layer 14 formed of a dry-film layer or a solder mask layer can be removed by chemical etching. On the other hand, the second insulating layer 14 formed of non-photoimagable material such as PET plastic or blue tape can be directly torn off.

As shown in FIG. 1H, the conductive layer 13 is removed by etching to fully expose the bumps 16.

As shown in FIG. 1I, the bumps 16 are reflowed to form semi-spherical metal connecting elements 16′ by surface tension and cohesion on the electrically connecting pads 110 of the circuit board 11.

Alternatively, the bumps 16 can be reflowed first to form metal connecting elements 16′ and then the second insulating layer 14 and the conductive layer 13 are removed.

Thus, the present invention directly forms the openings 15 through the first insulating layer 12, the conductive layer 13 and the second insulating layer 14 by only one opening process. Compared with the prior art two-time opening processes, the present invention avoids the difficulty of alignment in the prior art and becomes much simpler, thereby speeding up fabricating process and reducing fabricating cost.

In addition, because the present invention needs not increase the diameter of the openings to reduce the alignment difficulty, the diameter of the openings of the present invention can be designed much smaller, which makes it easy to meet the requirement of the fine pitch, thereby increasing the number of the electrically connecting pads per unit area.

### Second Embodiment

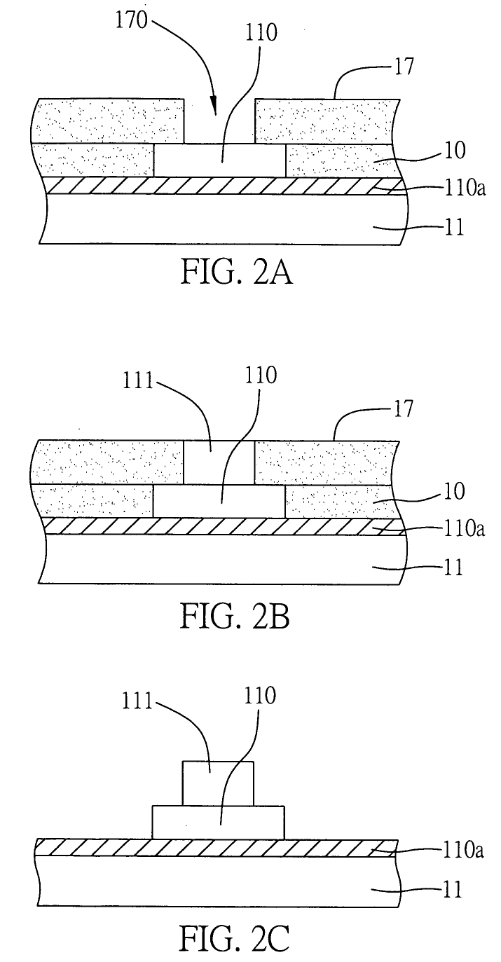

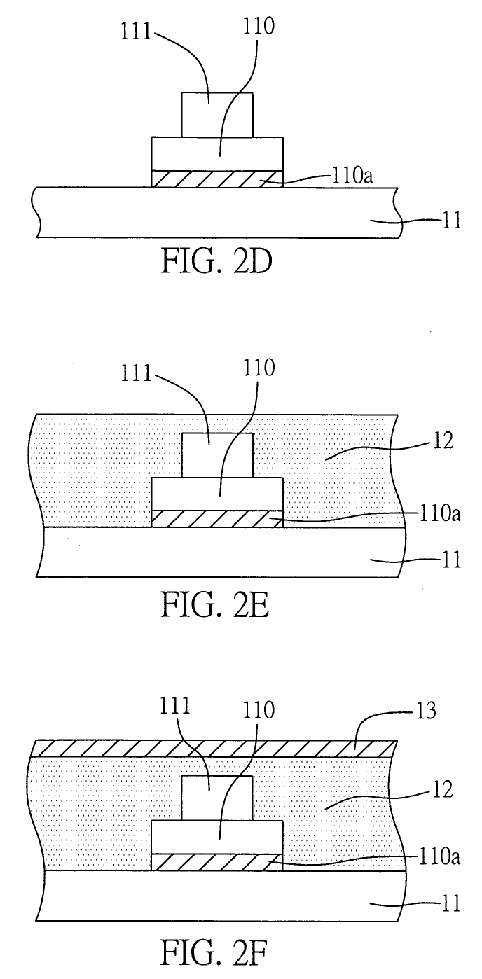

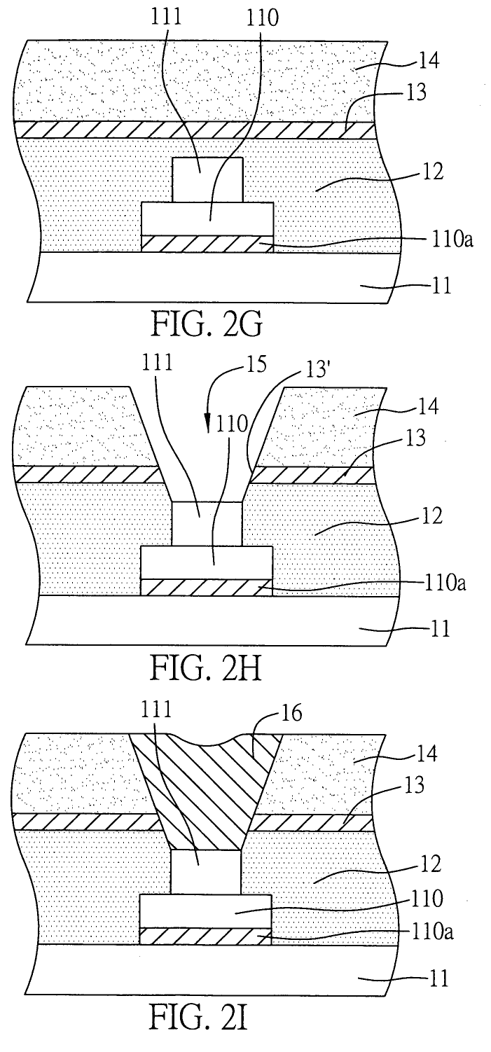

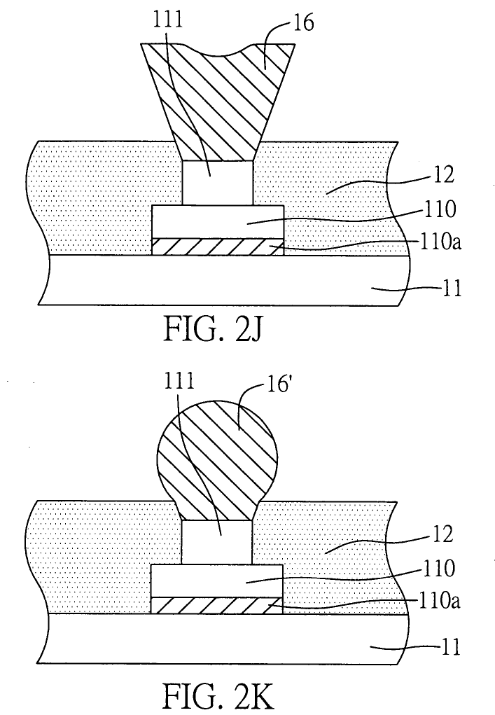

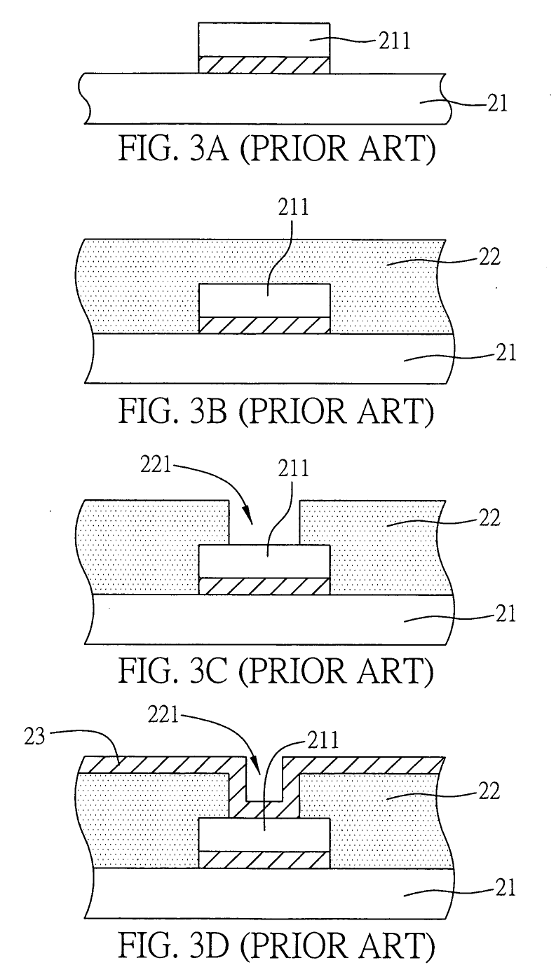

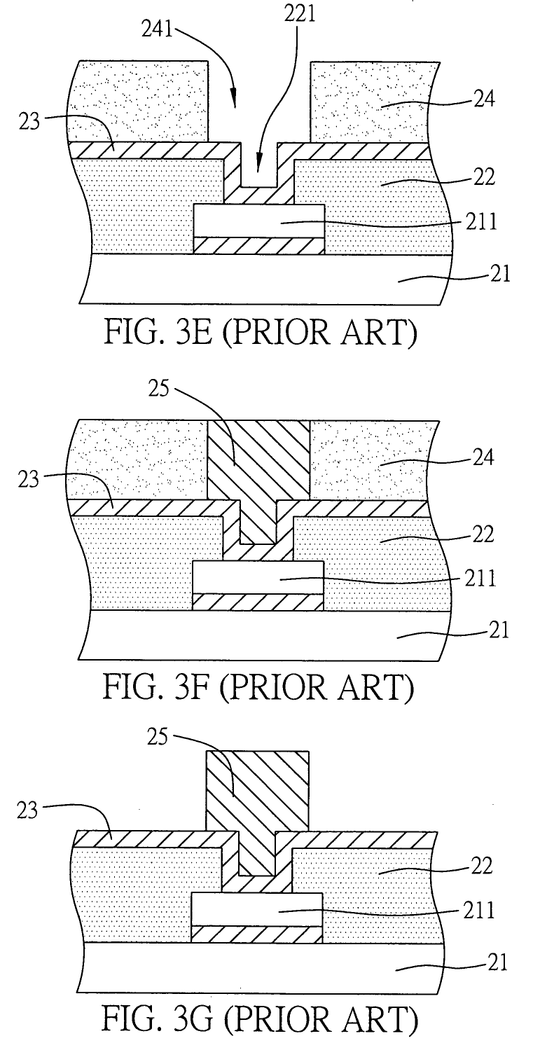

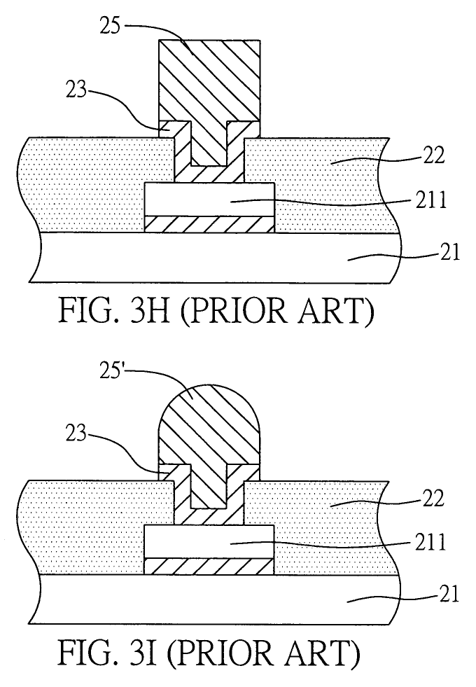

FIGS. 2A to 2K show another process according to a second embodiment of the present invention. The difference of the second embodiment from the first embodiment is that conductive posts are formed on top of the electrically connecting pads 110 to increase the height of connection. The detailed steps are described as follows.

As shown in FIG. 2A, a circuit board 11 with a conductive layer 110a formed thereon is provided first. The conductive layer 110a can be formed of a metal or an alloy selected from Cu, Sn, Ni, Cr, Ti, Cu—Cr alloy or Sn—Pb alloy or formed of a conductive polymer material. Then, a resist layer 10 patterned with a plurality of openings is formed on the surface of the conductive layer 110a. Subsequently, a plurality of electrically connecting pads 110 are formed in the openings of the resist layer 10 by electroplating. Then, another resist layer 17 is formed on the circuit board 11, which is patterned with openings 170 corresponding to the electrically connecting pads 110.

As shown in FIG. 2B, conductive posts 111 are formed in the opening 170 of the resist layer 17 by electroplating. The conductive posts 111 can be formed of Pb, Sn, Ag, Cu, Au, Bi, Sb, Zn, Ni, Zr, Mg, In, Te or Ga.

As shown in FIGS. 2C and 2D, the resist layers 17, 10 and the conductive layer 110a underneath the resist layers are removed to expose the conductive posts 111 and the electrically connecting pads 110.

As shown in FIG. 2E, a first insulating layer 12 is formed on the circuit board 11 by lamination, coating or printing, the first insulating layer 12 covering the electrically connecting pads 110 and the posts 111 on the electrically connecting pads 110.

As shown in FIG. 2F, a conductive layer 13 is formed on the first insulating layer 12.

As shown in FIG. 2G, a second insulating layer 14 is formed on the top of the conductive layer 13 by lamination, coating or printing.

As shown in FIG. 2H, a laser opening process is applied to the first insulating layer 12, the conductive layer 13 and the second insulating layer 14 directly over the conductive posts 111 to form openings 15 through the three layers, thereby exposing the conductive posts 111 and the edges 13′ of the conductive layer 13 via the openings 15.

As shown in FIG. 21, bumps 16 are formed in the openings 15 by electroplating through the conductive layer 13 as a current conductive path. The bump 16 can be made from a metal or an alloy selected from Pb, Sn, Ag, Cu, Bi, Sb, Zn, Ni, Zr, Mg, In, Te, Au and Ga.

As shown in FIG. 2J, the second insulating layer 14 and the conductive layer 13 are successively removed by chemical stripping or physics stripping to expose the bumps 16.

As shown in FIG. 2K, the bumps 16 are reflowed to form semi-spherical metal connecting elements 16′ on the conductive posts 111.

Alternatively, the bumps 16 can be reflowed first to form metal connecting elements 16′ and then the second insulating layer 14 and the conductive layer 13 are removed.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabricating process of an electrically conductive structure on a circuit board, comprising:
providing a circuit board with a plurality of electrically connecting pads formed thereon;
forming a first insulating layer on the circuit board, the first insulating layer covering the electrically connecting pads;
forming a conductive layer on the first insulating layer;
forming a second insulating layer on the conductive layer;
applying an opening process to the first insulating layer, the conductive layer and the second insulating layer directly over the electrically connecting pads to form openings through the three layers corresponding in position to the electrically connecting pads; and forming bumps in the openings by electroplating.

2. The fabricating process of claim 1, further comprising reflowing the bumps first and then removing the second insulating layer and the conductive layer.

3. The fabricating process of claim 1, further comprising removing the second insulating layer and the conductive layer and then reflowing the bumps.

4. The fabricating process of claim 1, wherein fabricating process of the electrically connecting pads comprising:
providing a circuit board with a conductive layer formed thereon;
forming a resist layer with openings on the surface of the conductive layer;
forming electrically connecting pads in the openings of the resist layer by electroplating; and removing the resist layer and the conductive layer underneath the resist layer.

5. The fabricating process of claim 1, wherein the conductive layer is removed by etching.

6. The fabricating process of claim 1, wherein the second insulating layer is formed on the conductive layer by one of the methods consisting of lamination, coating and printing.

7. The fabricating process of claim 1, wherein the second insulating layer is removed by one of the methods consisting of chemical stripping and physics stripping.

8. The fabricating process of claim 1, wherein the openings are laser openings.

9. A fabricating process of an electrically conductive structure on a circuit board, comprising:
providing a circuit board with a plurality of electrically connecting pads formed thereon, the electrically connecting pads having posts formed on surfaces thereof;
forming a first insulating layer on the circuit board, the first insulating layer covering the electrically connecting pads and the posts on the electrically connecting pads;
forming a conductive layer on the first insulating layer;
forming a second insulating layer on the conductive layer;
applying an opening process to the first insulating layer, the conductive layer and the second insulating layer directly over the posts to form openings through the three layers corresponding in position to the posts to expose the posts via the openings; and
forming bumps in the opening by electroplating.

10. The fabricating process of claim 9, further comprising reflowing the bumps first and then removing the second insulating layer and the conductive layer.

11. The fabricating process of claim 9, further comprising removing the second insulating layer and the conductive layer first and then reflowing the bumps.

12. The fabricating process of claim 9, wherein fabricating process of the electrically connecting pads having posts formed on the surfaces thereof comprising:
providing a circuit board with a conductive layer formed thereon;
forming a first resist layer patterned with openings on the conductive layer;
forming electrically connecting pads in the openings of the first resist layer by electroplating;
forming a second resist layer on the circuit board patterned with openings corresponding to the electrically connecting pads;
forming conductive posts in the openings of the second resist layer by electroplating; and
removing the first and second resist layers and the conductive layer underneath the first resist layer.

13. The fabricating process of claim 9, wherein the conductive layer is removed by etching.

14. The fabricating process of claim 9, wherein the second insulating layer is formed on the conductive layer by one of the methods consisting of lamination, coating and printing.

15. The fabricating process of claim 9, wherein the second insulating layer is removed by one of the methods consisting of chemical stripping and physics stripping.

16. The fabricating process of claim 9, wherein the openings are laser openings.
